(19) United States
(12) Patent Application Publication
(10) Pub. No.: US 2014/0379978 A1
(43) Pub. Date: Dec. 25, 2014

(54) REFRESH SCHEME FOR MEMORY CELLS WITH WEAK RETENTION TIME

(71) Applicant: QUALCOMM Incorporated, San Diego, CA (US)

(72) Inventors: Jung Pill KIM, San Diego, CA (US); Xiangyu DONG, San Diego, CA (US); Jungwon SUH, San Diego, CA (US)

(73) Assignee: QUALCOMM Incorporated, San Diego, CA (US)

(21) Appl. No.: 14/242,769

(22) Filed: Apr. 1, 2014

Related U.S. Application Data
(60) Provisional application No. 61/838,435, filed on Jun. 24, 2013.

(51) Int. Cl. G11C 11/401; G11C 11/406

(52) U.S. Cl. CPC G11C 11/401; G11C 11/40615
USPC 711/106

(57) ABSTRACT

A memory refresh method within a memory controller includes checking a first retention state corresponding to a first memory address and a second retention state corresponding to a second memory address. The memory refresh method also includes performing a refresh operation on a row corresponding to the second memory address when the second retention state indicates a weak retention state. The first memory address corresponds to a refresh counter address, and the second memory address corresponds to a complementary address of the refresh counter address.

### CROSS REFERENCE TO RELATED APPLICATION

The present application claims the benefit of U.S. Provisional Patent Application No. 61/838,435, filed on Jun. 24, 2013, in the names of Jung Pill Kim, et al., the disclosure of which is expressly incorporated by reference herein in its entirety.

### TECHNICAL FIELD

This disclosure relates to electronic memory operation and more specifically to a refresh scheme for memory cells with a weak retention time.

### BACKGROUND

Semiconductor memory devices include, for example, static random access memory (SRAM) and dynamic random access memory (DRAM). A DRAM memory cell generally includes one transistor and one capacitor, which enables a high degree of integration. The capacitor can be either charged or discharged to store information as a corresponding bit value (e.g., ‘0’ or ‘1’). Because capacitors leak charge, the stored information eventual fades unless the capacitor charge is refreshed periodically. Due to the refresh requirement, DRAM is referred to as dynamic memory as opposed to SRAM and other static memory. The continuous refreshing of DRAM generally limits its use to computer main memory.

DRAM scaling continues to increase the total number of bits for each DRAM chip, directly impacting the specification of DRAM refresh, the process by which a cell's value is kept readable. The specification of DRAM refresh includes the interval at which refresh commands are sent to each DRAM (tREFI) and the amount of time that the refresh command occupies the DRAM interface (tRFC). Unfortunately, DRAM scaling increases the number of weak retention cells (e.g., cells that have a reduced retention time). Such cells involve additional refresh cycles to maintain the stored information. A significant performance and power consumption impact is caused by the increased refresh cycles in a system on chip or other like computer architecture. Otherwise, potential DRAM chip yield loss results without increased refresh cycles.

### SUMMARY

According one aspect of the present disclosure, a memory refresh method within a memory controller includes checking a first retention state corresponding to a first memory address and a second retention state corresponding to a second memory address. The method also includes performing a refresh operation on a row corresponding to the second memory address when the second retention state indicates a weak retention state. The first memory address corresponds to a refresh counter address, and the second memory address corresponds to a complementary address of the refresh counter address.

According another aspect of the present disclosure, a memory controller includes a dynamic memory and a refresh control block coupled to the dynamic memory. The refresh control block includes a refresh counter, a retention state table, and control logic. The control logic checks a first retention state corresponding to a first memory address from the retention state table and a second retention state corresponding to a second memory address from the retention state table. The control logic also inserts a refresh operation when the second retention state indicates a weak retention state. The first memory address corresponds to a refresh counter address, and the second memory address corresponds to a complementary address of the refresh counter address.

According another aspect of the present disclosure, a memory controller includes a dynamic memory and a refresh control block coupled to the dynamic memory. The refresh control block includes a refresh counter, a retention state table, and control logic. The control logic includes means for checking a first retention state corresponding to a first memory address from the refresh counter and a second retention state corresponding to a second memory address from the retention state table. The control logic also includes means for performing a refresh operation on a row corresponding to the second memory address when the second retention state indicates a weak retention state.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following descriptions taken in conjunction with the accompanying drawings.

FIGS. 1A and 1B illustrate circuit timing diagrams that show techniques for increasing a refresh frequency of memory cells with a weak retention state, while maintaining a refresh frequency for other memory cells, according to aspects of the present disclosure.

FIG. 2A is a block diagram illustrating a memory controller including a refresh control block according to an aspect of the present disclosure.

FIG. 2B illustrates a refresh table to provide a retention state corresponding to each respective memory address according to an aspect of the present disclosure.

FIG. 3 is a flow chart illustrating a refresh scheme for memory cells with a weak retention state according to an aspect of the present disclosure.

FIG. 4A is a block diagram illustrating a memory controller including a refresh control block according to another aspect of the present disclosure.

FIG. 4B illustrates a refresh table to provide a memory address having a weak retention state according to an aspect of the present disclosure.

FIG. 5 is a flow chart illustrating a refresh scheme for memory cells with a weak retention state according to another aspect of the present disclosure.

FIG. 6 is a flow chart illustrating a method for refreshing memory cells with a weak retention time according to an aspect of the present disclosure.

FIG. 7A illustrates circuit timing diagrams that show techniques for increasing a refresh frequency of memory cells with a weak retention state, while maintaining a refresh frequency for other memory cells, according to aspects of the present disclosure.

FIG. 7B illustrates a refresh table according to an aspect of the present disclosure.

FIG. 8 illustrates a refresh table to provide a retention state corresponding to each respective memory address according to an aspect of the present disclosure.

FIG. 9 is a block diagram showing an exemplary wireless communication system in which aspects of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Dynamic random access memory (DRAM) scaling continues to increase the total number of bits per DRAM chip. This increased capacity directly impacts the specification of DRAM refresh, the process by which a bit cell's value is kept readable. The specification of DRAM refresh includes the interval at which refresh commands are sent to each DRAM (tREFI), and the amount of time that the refresh command occupies the DRAM interface (tRFC). Unfortunately, DRAM scaling also increases the number of weak retention cells (e.g., cells that have a reduced retention time). Such cells involve increased refresh cycles to maintain the stored information. Performance and power consumption are significantly impacted by the increased refresh cycles on a DRAM in a system on chip (SoC) or other like computer architecture. Potential DRAM chip yield loss from the increased number of weak retention cells results without the increased refresh cycles.

One aspect of the present disclosure inserts a refresh cycle for cells with a weak retention state, with a nominal increase to the refresh period (e.g., the refresh interval tREFI). In one configuration, a refresh control block tests a first retention state corresponding to a first memory address and a second retention state corresponding to a second memory address. In this configuration, the first memory address corresponds to a refresh counter address and the second memory address is a complementary address of the refresh counter address (e.g., the refresh counter address with an inverted most significant bit (MSB)). In operation, a refresh operation is performed on the second memory address when the retention state of the second memory address indicates a weak retention state. The refresh operation on the second memory address may be performed before, after or concurrent with the refresh operation on the first memory address.

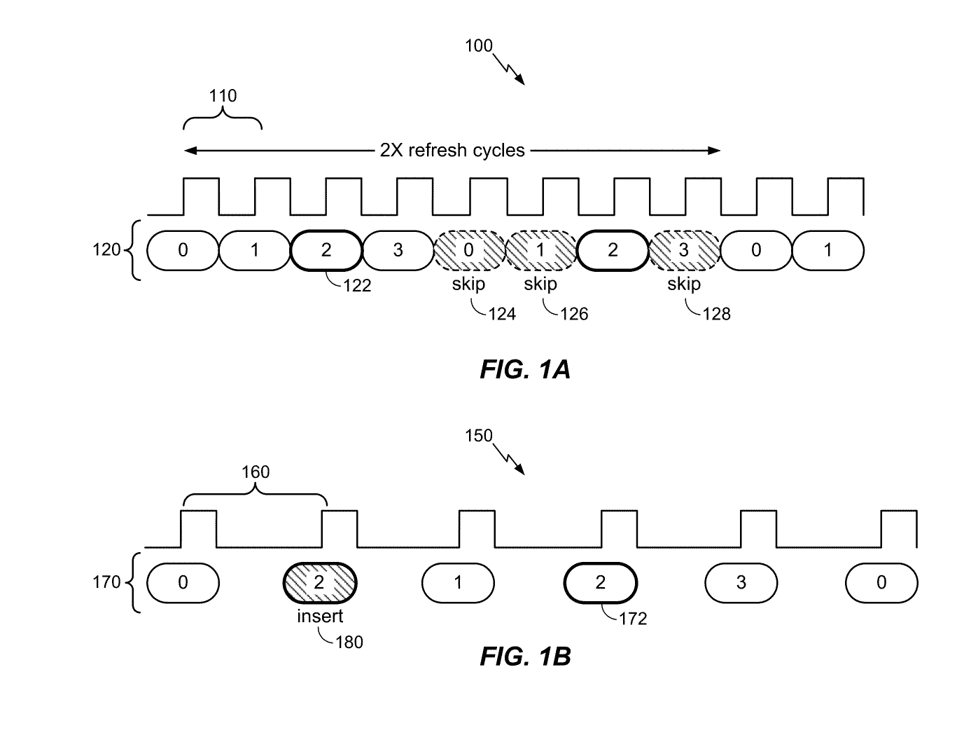

FIGS. 1A and 1B illustrate circuit timing diagrams that show techniques for increasing a refresh frequency of memory cells (e.g., rows) with a weak retention state, while maintaining a refresh frequency for other memory cells, according to aspects of the present disclosure. FIG. 1A shows a timing diagram 100 with a double refresh cycle 110 for performing refresh operations on refresh addresses 120. The double refresh cycle 110 may be, 16 microseconds (μs),for example, in case of a 32 microseconds (μs) refresh specification. In this example, there are four rows of memory, with a refresh address 122 having a weak retention state. Representatively, refresh operations are performed on refresh addresses 0, 1, 2 and 3. In this example, however, refresh operations on the refresh address 124, the refresh address 126 and the refresh address 128 are skipped during a subsequent pass. As shown in FIG. 1A, the refresh cycle is doubled for the refresh address 122 having the weak retention state, while skipping the refresh cycles for the refresh addresses with a normal retention state.

FIG. 1B shows a timing diagram 150 with a single refresh cycle 160 for performing refresh operation on refresh addresses 170. The single refresh cycle 160 may be, for example, thirty-two (32) microseconds (μs). In this example, there are also four rows of memory, with a refresh address 172 having a weak retention state. Representatively, an inserted refresh operation 180 is performed on the refresh address 172 with the weak retention state. In this example, weak row refresh cycles are inserted. As shown in FIGURE 1B, the refresh cycle is doubled for only the refresh address 172 with the weak retention state, with only a nominal increase to the refresh cycle for the refresh addresses with a normal retention state.

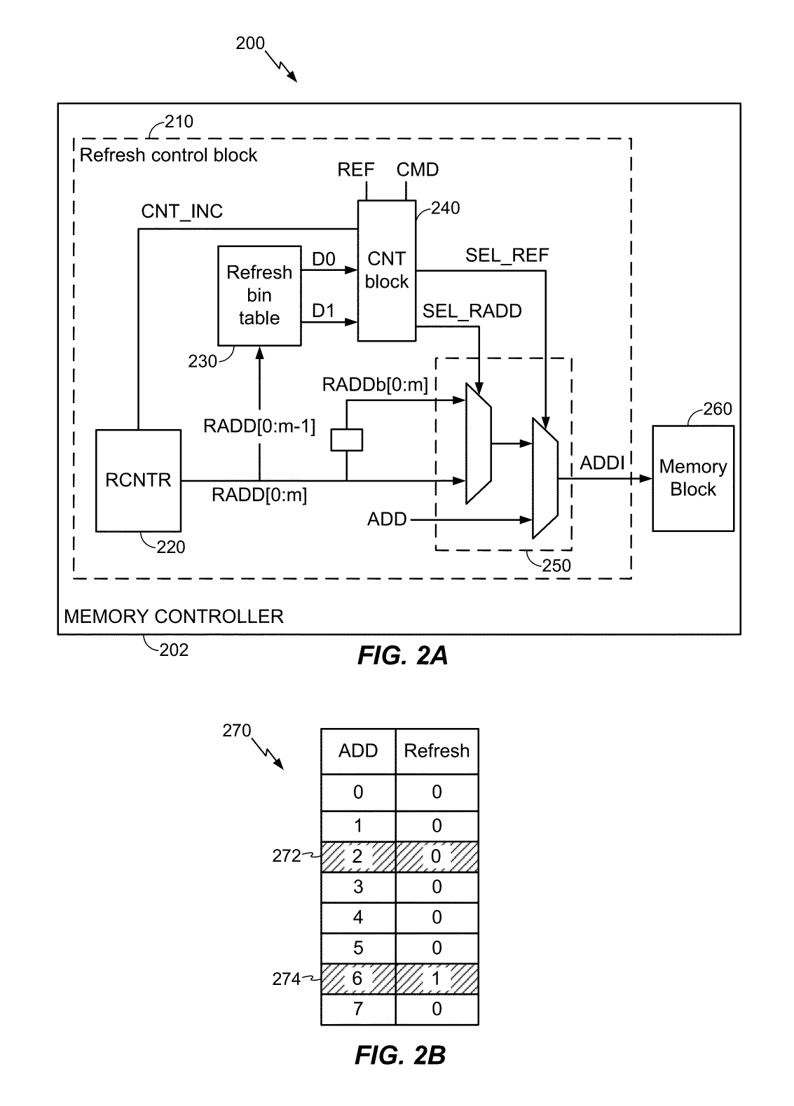

FIG. 2A is a block diagram 200 illustrating a memory controller 202 including a refresh control block 210 according to an aspect of the present disclosure. In this configuration, the refresh control block 210 includes a refresh counter 220, a refresh bin table 230, a counter block 240 and refresh control logic 250. In one configuration, a refresh bin table 230 is used to store a retention state corresponding to each memory address. In this configuration, the refresh bin table 230 enables access to two refresh bin table entries using a single refresh counter address (RADD) and a complementary refresh counter address (RADDb). In this example, the complementary refresh counter address RADDb corresponds to the refresh counter address RADD with an inverted most significant bit (MSB). When the retention state corresponding to the complementary refresh counter address RADDb indicates a weak retention state, the refresh control logic 250 performs a refresh operation on a row corresponding to the complementary refresh counter address RADDb within a memory block 260.

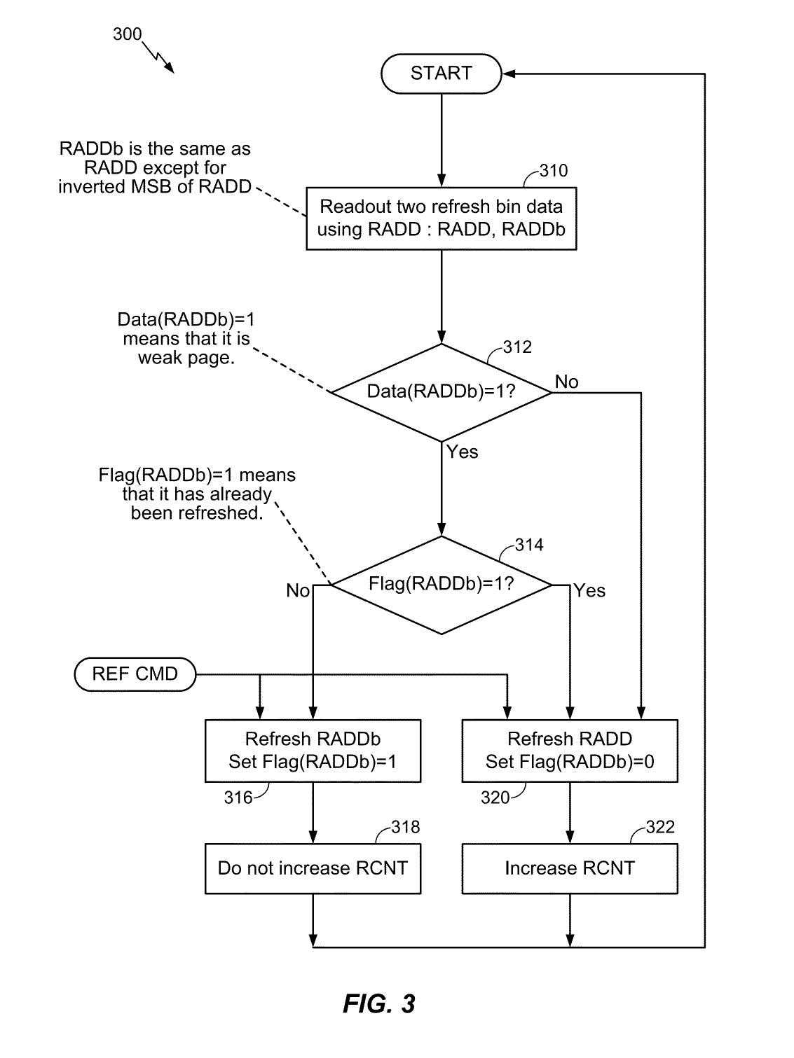

FIG. 2B illustrates a refresh table 270 to provide a retention state corresponding to each respective memory address according to an aspect of the present disclosure. The entries in the refresh table 270 may be used to populate the refresh bin table 230 of FIG. 2A. In this example, the complementary refresh counter address 274 has a weak retention state (e.g., ‘1’ corresponds to a weak retention state). During operation, a retention state is determined for the refresh counter address 272 (e.g., RADD is ‘010’), and the complementary refresh counter address 274 (e.g., RADDb is binary ‘110’). Because the complementary refresh counter address 274 has a weak retention state, the refresh control logic 250 of FIG. 2A inserts a refresh operation prior to the refresh operation on the refresh counter address 272, as further illustrated in FIG. 3.

FIG. 3 is a flow chart 300 illustrating a refresh scheme for memory cells with a weak retention state according to an aspect of the present disclosure. At block 310, two retention states are read using a single refresh counter address RADD. For example, as shown in FIG. 2A, the refresh bin table outputs a retention state corresponding to the refresh counter address RADD and the complementary refresh counter address RADDb. At block 312, it is determined whether the retention state corresponding to the complementary refresh counter address RADDb is a weak retention state. When the retention state of the complementary refresh counter address RADDb is normal, a refresh operation is performed for the refresh counter address RADD at block 320. At block 322, a refresh counter value (RCNT) is incremented. Otherwise, at block 314, it is determined whether a refresh operation has been performed on the complementary refresh counter address RADDb. When the refresh operation has not been performed, a refresh operation for the complementary refresh counter address RADDb is performed at block 316. At block 318, the refresh counter RCNT is not incremented so that a refresh operation is subsequently performed on the refresh counter address RADD.

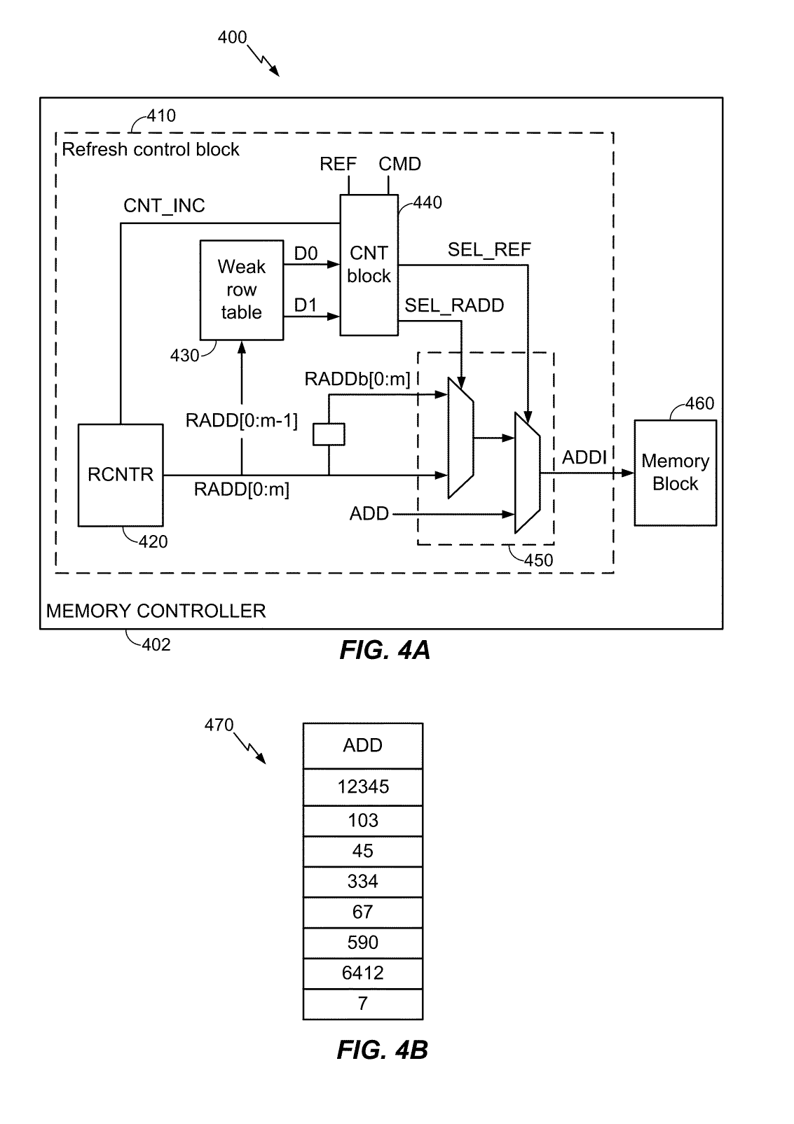

FIG. 4A is a block diagram 400 illustrating a memory controller 402 including a refresh control block 410, according to another aspect of the present disclosure. In this configuration, the refresh control block 410 includes a refresh counter 420, a weak row table 430, a counter block 440 and refresh control logic 450. In this aspect of the disclosure, the configuration of the refresh control block 410 is similar to the configuration of the refresh control block 210 shown in FIG. 2A; however, the weak row table 430 replaces the refresh bin table 230 of FIG. 2A. In this configuration, the weak row table 470, which is further illustrated in FIG. 4B, includes only the memory address with a corresponding weak retention state. By contrast, the refresh bin table 230 of FIG. 2B includes each memory address as well as the corresponding retention state of each memory address within, for example, the memory block 260.

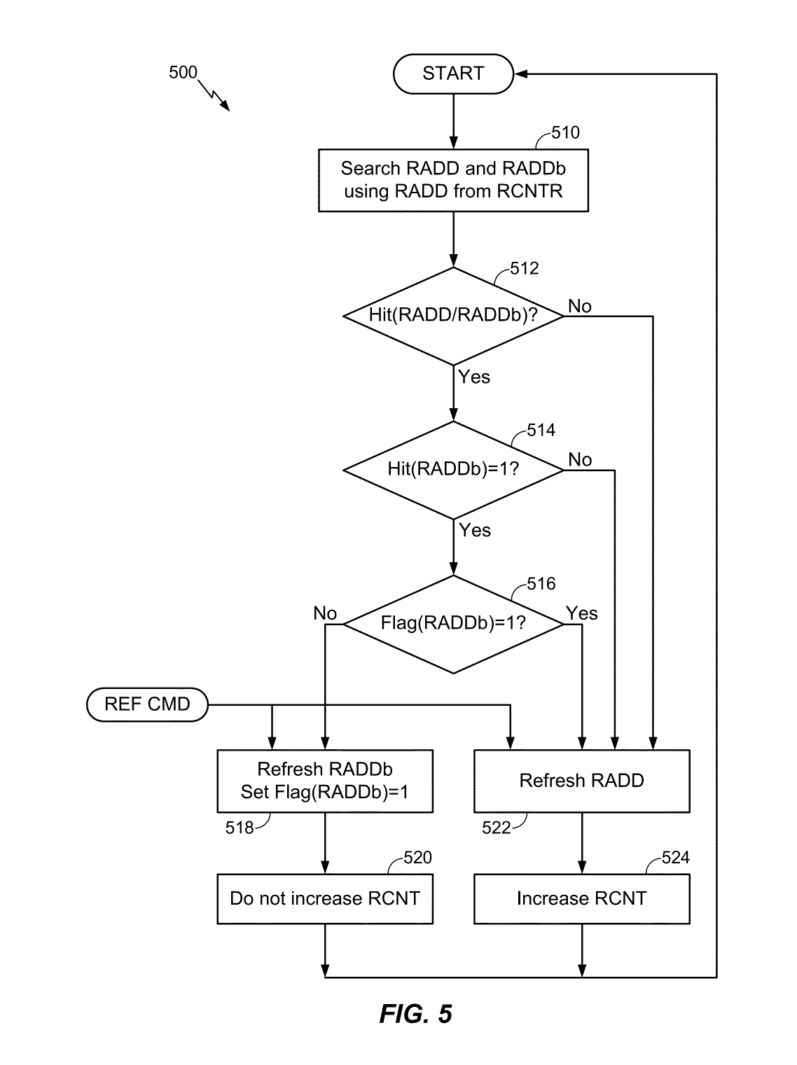

FIG. 5 is a flow chart 500 illustrating a refresh scheme for memory cells with a weak retention state according to another aspect of the present disclosure. At block 510, the refresh counter address RADD and the complementary refresh counter address RADDb are used to search a weak row table. For example, the refresh counter address RADD and the complementary refresh counter address RADDb are used to search the weak row table 430/470, as shown in FIGS. 4A and 4B. At block 512, it is determined whether a hit is detected in the weak row table. When a hit is detected from the complementary refresh counter address RADDb at block 514, at block 516, it is determined whether a refresh operation has been performed for the complementary refresh counter address RADDb. When the refresh operation has not been performed, the refresh operation on the complementary refresh counter address RADDb is performed at block 518. At block 520, the refresh count RCNT is not incremented so that a refresh operation is performed on the refresh counter address RADD at block 522. At block 524, the refresh counter value (RCNT) is incremented.

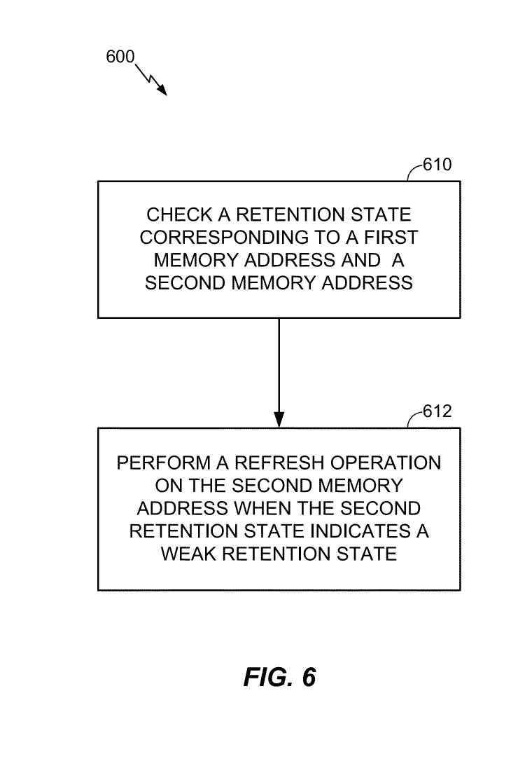

FIG. 6 is a flow chart illustrating a method 600 for refreshing memory cells with a weak retention time according to an aspect of the present disclosure. At block 610, a first retention state corresponding to a first memory address and a second retention state corresponding to a second memory address are checked. For example, as shown in FIG. 2A, the refresh bin table outputs a retention state corresponding to a refresh address RADD and a complementary refresh address RADDb. Alternatively, the refresh address RADD and the complementary refresh address RADDb are used to search the weak row table 430/470, as shown in FIGS. 4A and 4B. At block 612, a refresh operation is performed on a row corresponding to the second memory address when the second retention state indicates a weak retention state. For example, as shown in FIG. 2A, when the retention state corresponding to a complementary refresh counter address RADDb indicates a weak retention state, the refresh control logic 250 performs a refresh operation on a row corresponding to the complementary refresh counter address RADDb within the memory block 260. The refresh operation for the complementary refresh counter address RADDb may be performed before, after or concurrent with the refresh operation for the refresh counter address RADD.

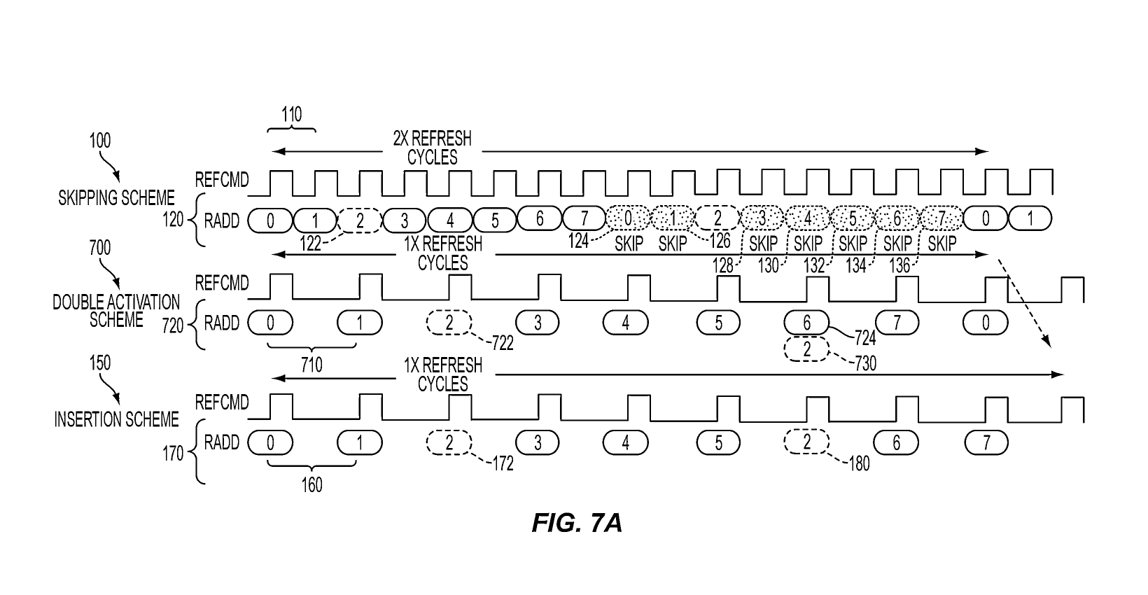

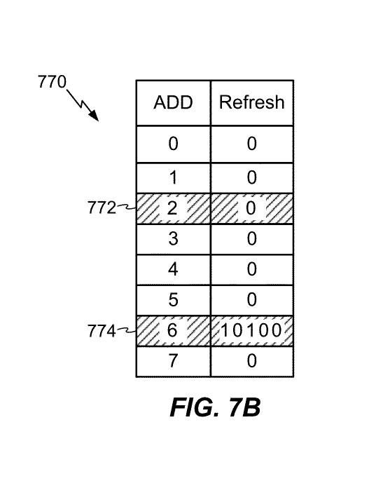

FIG. 7A illustrate circuit timing diagrams that show techniques for increasing a refresh frequency of memory cells (e.g., rows) with a weak retention state, while maintaining a refresh frequency for other memory cells, according to aspects of the present disclosure. A timing diagram 100 has a double refresh cycle 110 for performing refresh operations on refresh addresses 120. The double refresh cycle 110 may be, for example, sixteen (16) microseconds (μs) when a 32 microseconds (μs) refresh is specified. In this example, there are eight rows of memory, with a refresh address 122 having a weak retention state. Representatively, refresh operations are performed on refresh addresses 0, 1, 2, 3, 4, 5, 6 and 7. In this example, however, refresh operations on the refresh address 124, the refresh address 126, the refresh address 128, the refresh address 130, the refresh address 132, the refresh address 134, and the refresh address 128 are skipped during a subsequent pass. As shown in the timing diagram 100, the refresh cycle is doubled for the refresh address 122 having the weak retention state, while skipping the refresh cycles for the refresh addresses with a normal retention state.

The timing diagram 150 shows a single refresh cycle 160 for performing refresh operation on refresh addresses 170. The single refresh cycle 160 may be, for example, thirty-two (32) microseconds (μs). In this example, there are also eight rows of memory, with a refresh address 172 having a weak retention state. Representatively, an inserted refresh operation 180 is performed on the refresh address 172 with the weak retention state. In this example, weak row refresh cycles are inserted. As shown in the timing diagram 150, the refresh cycle is doubled for only the refresh address 172 with the weak retention state, while maintaining the refresh cycle for the refresh addresses with a normal retention state.

For the insertion scheme shown in the timing diagram 150, the 1× refresh cycle increases as much as the percentage (%) of the inserted weak rows (e.g., the refresh address 172). In this example, to keep the same refresh cycle retention specification of, for example 8K cycles/32 ms, a refresh cycle retention specification may be modified as follows:

(8K+% of the weak rows)cycles/32 ms. (1)

For example, if the percentage of weak rows equals five percent (5%), then 8.4K cycles/32 ms or 8K cycles/30.4 s may be specified as the refresh cycle retention specification.

A timing diagram 700 shows a double activation scheme for increasing a refresh frequency of memory cells (e.g., rows) with a weak retention state, while maintaining a refresh cycle retention specification, according to aspects of the present disclosure. The timing diagram 700 is shown with a single refresh cycle 710 for performing a refresh operation on refresh addresses 720. The single refresh cycle 710 may be, for example, thirty-two (32) microseconds (μs). In this example, there are also eight rows of memory, with a refresh counter address 722 having a weak retention state. Representatively, an inserted refresh operation 730 is performed on the refresh address 722 with the weak retention state. In this example, however, the inserted refresh operation 730 is performed concurrently with the refresh operation for the refresh address 724. As shown in the timing diagram 700, the refresh cycle is doubled for only the refresh address 722 with the weak retention state, while maintaining the refresh cycle retention specification (e.g., 8K cycles/32 ms).

FIG. 7B illustrates a refresh table 770 to provide a retention state corresponding to each respective memory address according to an aspect of the present disclosure. The entries in the refresh table 770 may populate a refresh table (e.g., the refresh bin table 230 of FIG. 2A or the weak row table 430 of FIG. 4A). In this example, the complementary refresh counter address 774 has a weak retention state (e.g., ‘10100’ corresponds to a weak retention state). In this example, however, weak retention state also identifies a weak internal row from a group of internal rows (e.g. 32) corresponding to the complementary refresh counter address 774.

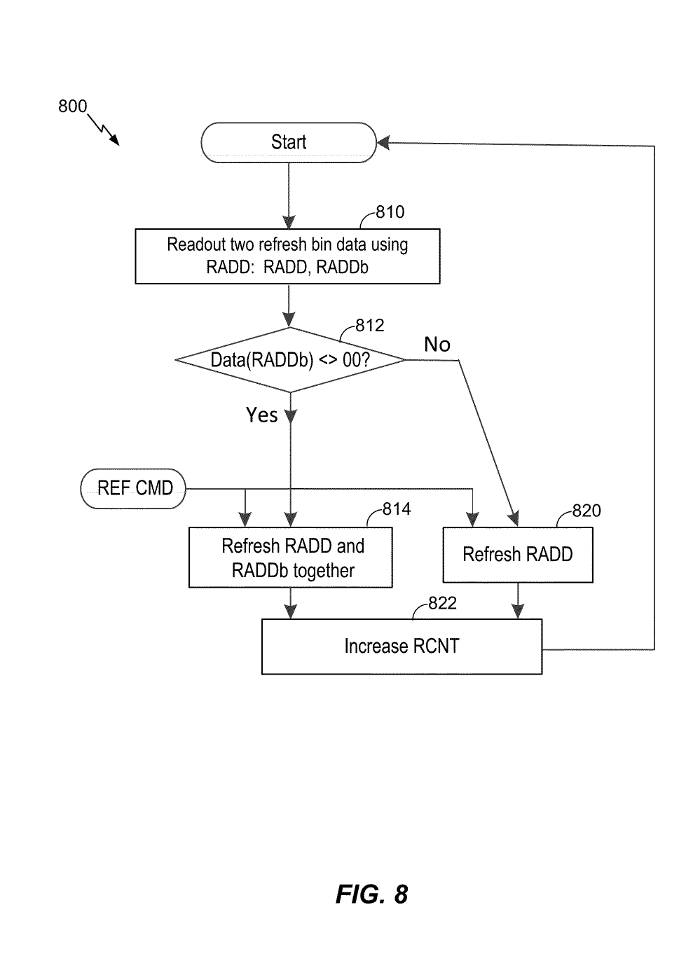

During operation, a retention state is determined for the refresh counter address 272 (e.g., RADD is ‘010’) and the complementary refresh counter address 274 (e.g., RADDb is binary ‘110’). Because the complementary refresh counter address 774 has a weak retention state, a refresh operation may be performed for the corresponding weak internal row concurrent to the refresh operations for a group of internal rows corresponding to the refresh counter address 772, as further illustrated in FIG. 8. In this configuration, limiting the concurrent refresh operation to only the weak internal rows from the group of internal rows corresponding to the complementary refresh counter address 774 reduces power noise (as opposed to performing concurrent refresh operations on each of 64 internal rows corresponding to the refresh counter address 772 and the complementary refresh counter address 774).

FIG. 8 is a flow chart 800 illustrating a refresh scheme for memory cells with a weak retention state according to another aspect of the present disclosure. At block 810, the refresh counter address RADD and the complementary refresh counter address RADDb are read from a refresh table. At block 812, it is determined whether the retention state corresponding to the complementary refresh counter address RADDb is a weak retention state. When the retention state of the complementary refresh counter address RADDb is normal, a refresh operation is performed for the refresh counter address RADD at block 820. At block 822, a refresh counter value (RCNT) is incremented. Otherwise, at block 814, a refresh operation for the complementary refresh counter address RADDb is performed together with refresh operation for the refresh counter address RADD. In one configuration, the weak retention state identifies the weak internal row from the group of internal rows (e.g. 32) corresponding to the complementary refresh counter address RADDb. In this configuration, the concurrent refresh operation is only performed on the weak internal rows from the group of internal rows corresponding to the complementary refresh counter address RADDb.

In one configuration, the information for the weak rows should be provided from the DRAM to the system on chip (SoC). Thus, the SoC can adjust refresh cycles. One such implementation is to have read only mode register set (MRS) mode in the DRAM with the weak row % information. The SoC can read the information and adjust refresh cycles.

In one configuration, a memory controller includes a refresh control block. The refresh control block includes a refresh counter, a refresh bin table and a counter block. The refresh control block includes means for checking a first retention state corresponding to a first memory address from the refresh counter and a second retention state corresponding to a second memory address from the retention state table. In one aspect of the disclosure, the checking means may be the refresh control logic 250/450 configured to perform the functions recited by the checking means. In this configuration, the refresh control block also includes means for performing a refresh operation on a row corresponding to the second memory address when the second retention state indicates a weak retention state. In one aspect of the disclosure, the performing means may be the refresh control logic 250/450 configured to perform the functions recited by the performing means. In another aspect, the aforementioned means may be any module or any apparatus configured to perform the functions recited by the aforementioned means.

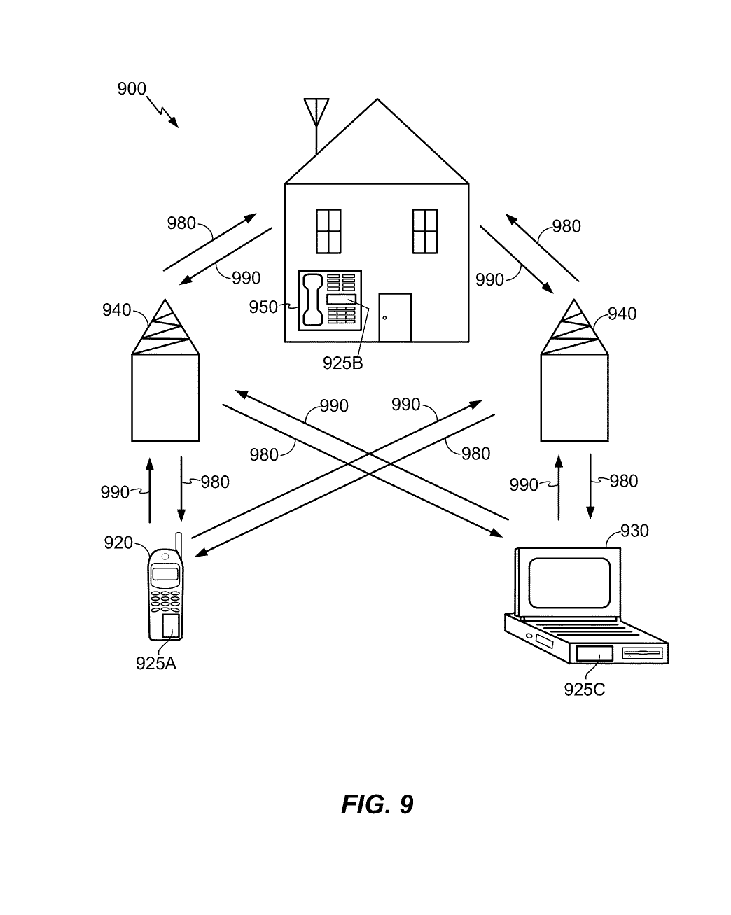

FIG. 9 shows an exemplary wireless communication system 900 in which an aspect of the disclosure may be advantageously employed. For purposes of illustration, FIG. 9 shows three remote units 920, 930, and 950 and two base stations 940. It will be recognized that typical wireless communication systems may have many more remote units and base stations. Remote units 920, 930, and 950 include memory controller circuitry 925A, 925B, and 925C, respectively, which are aspects of the disclosure as discussed further below. FIG. 9 shows forward link signals 980 from the base stations 940 and the remote units 920, 930, and 950 and reverse link signals 990 from the remote units 920, 930, and 950 to base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 9 illustrates memory controller circuitry according to the teachings of the disclosure, the disclosure is not limited to these exemplary illustrated units. For instance, memory controller circuitry according to aspects of the present disclosure may be suitably employed in any device.

Although specific circuitry has been set forth, it will be appreciated by those skilled in the art that not all of the disclosed circuitry is required to practice the disclosure. Moreover, certain well known circuits have not been described, to maintain focus on the disclosure. Similarly, although the description refers to logical “0” and logical “1” in certain locations, one skilled in the art appreciates that the logical values can be switched, with the remainder of the circuit adjusted accordingly, without affecting operation of the present disclosure.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A memory refresh method within a memory controller, comprising:
checking a first retention state corresponding to a first memory address and a second retention state corresponding to a second memory address; and
performing a refresh operation on a row corresponding to the second memory address when the second retention state indicates a weak retention state, in which the first memory address corresponds to a refresh counter address, and the second memory address corresponds to a complementary address of the refresh counter address.

2. The memory refresh method of claim 1, further comprising:
performing a refresh operation on a row corresponding to the first memory address after performing the refresh operation on the row corresponding to the second memory address; or
performing the refresh operation on the row corresponding to the first memory address before performing the refresh operation on the row corresponding to the second memory address.

3. The memory refresh method of claim 1, in which checking the first retention state comprises reading the first retention state of the first memory address and the second retention state of the second memory address from a one-time programmable memory.

4. The memory refresh method of claim 3, in which the one-time programmable memory includes each memory address and a retention state corresponding to each respective memory address.

5. The memory refresh method of claim 3, in which the one-time programmable memory includes each memory address having the weak retention state.

6. The memory refresh method of claim 1, in which checking the first retention state comprises determining whether a hit is detected with the first memory address or the second memory address from a weak row table.

7. The memory refresh method of claim 1, further comprising performing the refresh operation on a row corresponding to the first memory address concurrent with performing the refresh operation on the row corresponding to the second memory address.

8. The memory refresh method of claim 1, further comprising performing the refresh operation on a first plurality of internal rows corresponding to the first memory address concurrent with performing the refresh operation on an internal weak row from a second plurality of internal rows corresponding to the second memory address, the internal weak row being identified by the second retention state.

9. The memory refresh method of claim 1, in which the first memory address corresponds to the refresh counter address, and the second memory address corresponds to the refresh counter address with a complementary most significant bit.

10. The memory refresh method of claim 1, in which the memory refresh method is performed during a row address store (RAS) refresh cycle.

11. The memory refresh method of claim 1, in which the memory controller is integrated in a mobile phone, a set top box, a music player, a video player, an entertainment unit, a navigation device, a computer, a hand-held personal communication systems (PCS) unit, a portable data unit and/or a fixed location data unit.

12. A memory controller, comprising:
a dynamic memory; and
a refresh control block coupled to the dynamic memory, the refresh control block including a refresh counter, a retention state table, and control logic, the control logic operable:
to check a first retention state corresponding to a first memory address from the retention state table and a second retention state corresponding to a second memory address from the retention state table, and
to insert a refresh operation when the second retention state indicates a weak retention state in which the first memory address corresponds to a refresh counter address, and the second memory address corresponds to a complementary address of the refresh counter address.

13. The memory controller of claim 12, in which the retention state table comprises a one-time programmable memory including each memory address and a retention state corresponding to each respective memory address.

14. The memory controller of claim 12, in which the retention state table comprises a one-time programmable memory including each memory address having the weak retention state.

15. The memory controller of claim 12, in which the control logic is further operable:
to perform a refresh operation on a row corresponding to the first memory address after the refresh operation on the row corresponding to the second memory address;
to perform the refresh operation on the row corresponding to the first memory address before the refresh operation on the row corresponding to the second memory address; or
to perform the refresh operation on a row corresponding to the first memory address concurrent the refresh operation on the row corresponding to the second memory address.

16. The memory controller of claim 12, in which the control logic is further operable to perform the refresh operation on a first plurality of internal rows corresponding to the first memory address concurrent with performing the refresh operation on an internal weak row from a second plurality of internal rows corresponding to the second memory address, the internal weak row being identified by the second retention state.

17. The memory controller of claim 12, in which the first memory address corresponds to the refresh counter address, and the second memory address corresponds to the refresh counter address with a complementary most significant bit.

18. The memory controller of claim 12, in which the memory controller is integrated in a mobile phone, a set top box, a music player, a video player, an entertainment unit, a navigation device, a computer, a hand-held personal communication systems (PCS) unit, a portable data unit and/or a fixed location data unit.

19. A memory controller, comprising:
a dynamic memory; and
a refresh control block coupled to the dynamic memory, the refresh control block including a refresh counter, a retention state table, and control logic, the refresh control block comprising:
means for checking a first retention state corresponding to a first memory address from the refresh counter and a second retention state corresponding to a second memory address from the retention state table, and
means for performing a refresh operation on a row corresponding to the second memory address when the second retention state indicates a weak retention state.

20. The memory controller of claim 19, in which the memory controller further comprises:
means for performing a refresh operation on a row corresponding to the first memory address after performing the refresh operation on the row corresponding to the second memory address; or
means for performing the refresh operation on the row corresponding to the first memory address before performing the refresh operation on the row corresponding to the second memory address.

21. The memory controller of claim 19, in which the memory controller further comprises means for performing the refresh operation on a row corresponding to the first memory address concurrent with means for performing the refresh operation on the row corresponding to the second memory address.

22. The memory controller of claim 19, in which the memory controller further comprises means for performing the refresh operation on a first plurality of internal rows corresponding to the first memory address concurrent with means for performing the refresh operation on an internal weak row from a second plurality of internal rows corresponding to the second memory address, the internal weak row being identified by the second retention state.

23. The memory controller of claim 19, in which the retention state table comprises a one-time programmable memory including each memory address and a retention state corresponding to each respective memory address.

24. The memory controller of claim 19, in which the retention state table comprises a one-time programmable memory including each memory address having the weak retention state.

25. The memory controller of claim 19, in which the first memory address corresponds to a refresh counter address, and the second memory address corresponds to the refresh counter address with a complementary most significant bit.

26. The memory controller of claim 19, in which the memory controller is integrated in a mobile phone, a set top box, a music player, a video player, an entertainment unit, a navigation device, a computer, a hand-held personal communication systems (PCS) unit, a portable data unit and/or a fixed location data unit.

27. A memory refresh method within a memory controller, comprising:
the step of testing a first retention state corresponding to a first memory address and a second retention state corresponding to a second memory address; and
the step of performing a refresh operation on a row corresponding to the second memory address when the second retention state indicates a weak retention state.

28. The memory refresh method of claim 27, in which the memory controller is integrated in a mobile phone, a set top box, a music player, a video player, an entertainment unit, a navigation device, a computer, a hand-held personal communication systems (PCS) unit, a portable data unit and/or a fixed location data unit.
